(19) United States
(12) Patent Application Publication
(10) Pub. No.: US 2023/0185206 A1
(43) Pub. Date: Jun. 15, 2023

(54) APPARATUS FOR TREATING SUBSTRATE AND METHOD FOR TREATING A SUBSTRATE

(71) Applicant: SEMES CO., LTD., Cheonan-si (KR)

(72) Inventors: Tae Hee KIM, Yongin-si (KR); Ki Hoon CHOI, Cheonan-si (KR); Hyun YOON, Hwaseong-si (KR); Won Sik SON, Yongin-si (KR); Hyo Won YANG, Seoul (KR); In Ki JUNG, Hwaseong-si (KR)

(73) Assignee: SEMES CO., LTD., Cheonan-si (KR)

(21) Appl. No.: 17/901,103

(22) Filed: Sep. 1, 2022

(30) Foreign Application Priority Data
Sep. 2, 2021 (KR) 10-2021-0116912

(51) Int. Cl. G03F 7/20

(52) U.S. Cl. CPC G03F 7/70875; G03F 7/70025

(57) ABSTRACT

The inventive concept provides a mask treating apparatus. The mask treating apparatus includes a support unit configured to support and rotate a mask, the mask having a first pattern within a plurality of cells thereof and a second pattern outside regions of the plurality of cells; a heating unit including a laser irradiation module and a moving module, the laser irradiation module having a laser irradiator for irradiating a laser light to the second pattern, the moving module configured to change a position of the laser irradiation module; and a controller configured to control the support unit and the heating unit, and wherein when a treating position is divided into four equal parts from a first quadrant to a fourth quadrant based on a center of the mask, the laser irradiator is positioned at the fourth quadrant and the first quadrant in a direction linearly moving from a standby position to the treating position, positioned at the third quadrant in a direction which is perpendicular to the fourth quadrant, and positioned at the second quadrant in a direction which is perpendicular to the first quadrant, and wherein the controller controls a rotation of the support unit so the second pattern is positioned at the fourth quadrant.

### CROSS-REFERENCE TO RELATED APPLICATIONS

A claim for priority under 35 U.S.C. § 119 is made to Korean Patent Application No. 10-2021-0116912 filed on Sep. 2, 2021, in the Korean Intellectual Property Office, the entire contents of which are hereby incorporated by reference.

### BACKGROUND

Embodiments of the inventive concept described herein relate to a substrate treating apparatus and a substrate treating method, more specifically, a substrate treating apparatus and a substrate treating method for treating a substrate by heating the substrate.

In order to manufacture a semiconductor element, various processes such as a photolithography process, an etching process, an ashing process, an ion implantation process, and a thin film deposition process are performed on a substrate such as a wafer. Various treating liquids and treatment gases are used in each process. In addition, a drying process is performed on the substrate to remove a treating liquid used to treat the substrate from the substrate.

The photolithography process for forming a pattern on the wafer includes an exposing process. The exposing process is an operation which is previously performed for cutting a semiconductor integrated material attached to the wafer into a desired pattern. The exposing process may have various purposes such as forming a pattern for an etching and forming a pattern for the ion implantation. In the exposing process, the pattern is drawn in on the wafer with a light using a mask, which is a kind of ‘frame’. When the light is exposed to the semiconductor integrated material on the wafer, for example, a resist on the wafer, chemical properties of the resist change according to a pattern by the light and the mask. When a developing liquid is supplied to a resist which chemical properties have changed according to the pattern, the pattern is formed on the wafer.

In order to precisely perform the exposing process, the pattern formed on the mask must be precisely manufactured. To confirm that the pattern is formed in a desired form and precisely, an operator inspects a formed pattern using an inspection equipment such as a scanning electron microscope (SEM). However, a large number of patterns are formed on one mask. That is, it takes a lot of time to inspect all of the large number of patterns to inspect one mask.

Accordingly, a monitoring pattern capable of representing one pattern group including a plurality of patterns is formed on the mask. In addition, an anchor pattern that may represent a plurality of pattern groups are formed on the mask. The operator may estimate whether patterns formed on the mask are good or not through an inspecting of the anchor pattern. In addition, the operator may estimate whether patterns included in one pattern group are good or not through an inspecting of the monitoring pattern.

As described above, the operator may effectively shorten a time required for a mask inspection due to the monitoring pattern and the anchor pattern formed on the mask. However, in order to increase an accuracy of the mask inspection, it is preferable that critical dimension of the monitoring pattern and the anchor pattern are the same.

When an etching is performed to equalize the critical dimension of the monitoring pattern and the critical dimension of the anchor pattern, an over-etching may occur at the pattern. For example, a difference between an etching rate for the critical dimension of the monitoring pattern and an etching rate for the anchor pattern may occur several times, and in the process of repeatedly etching the monitoring pattern and/or the anchor pattern to reduce the difference, the over-etching may occur at the critical dimension of the monitoring pattern and the critical dimension of the anchor pattern. When the etching process is precisely performed to minimize an occurrence of such over-etching, the etching process takes a lot of time. Accordingly, a critical dimension correction process for precisely correcting the critical dimension of patterns formed on the mask is additionally performed.

FIG. 1 illustrates a normal distribution regarding a first critical dimension CDP1 of the monitoring pattern of the mask and a second critical dimension CDP2 (a critical dimension of the anchor pattern) before a critical dimension correction process is performed during a mask manufacturing process. In addition, the first critical dimension CDP1 and the second critical dimension CDP2 have a size smaller than a target critical dimension. Before the critical dimension correction process is performed, there is a deliberate deviation between the critical dimension of the monitoring pattern and the anchor pattern (CD, critical dimension). And, by additionally etching the anchor pattern in the critical dimension correction process, the critical dimension of these two patterns are made the same. In the process of over-etching the anchor pattern, if the anchor pattern is more over-etched than the monitoring pattern, a difference in the critical dimension of the monitoring pattern and the anchor pattern occurs, and thus the critical dimension of the patterns formed at the mask may not be accurately corrected. When additionally etching the anchor pattern, a precise etching with respect to the anchor pattern should be accompanied.

### SUMMARY

Embodiments of the inventive concept provide a substrate treating apparatus and a substrate treating method for efficiently treating a substrate.

Embodiments of the inventive concept provide a substrate treating apparatus and a substrate treating method for making a critical dimension of a pattern formed on a substrate uniform.

Embodiments of the inventive concept provide a substrate treating apparatus and a substrate treating method for precisely performing an etching on a specific pattern formed on a substrate.

Embodiments of the inventive concept provide a substrate treating apparatus and a substrate treating method for minimizing a structure of a heating unit provided on a substrate.

The technical objectives of the inventive concept are not limited to the above-mentioned ones, and the other unmentioned technical objects will become apparent to those skilled in the art from the following description.

The inventive concept provides a mask treating apparatus. The mask treating apparatus includes a support unit configured to support and rotate a mask, the mask having a first pattern within a plurality of cells thereof and a second pattern outside regions of the plurality of cells; a heating unit including a laser irradiation module and a moving module, the laser irradiation module having a laser irradiator for irradiating a laser light to the second pattern, the moving module configured to change a position of the laser irradiation module; and a controller configured to control the support unit and the heating unit, and wherein when a treating position is divided into four equal parts from a first quadrant to a fourth quadrant based on a center of the mask, the laser irradiator is positioned at the fourth quadrant and the first quadrant in a direction linearly moving from a standby position to the treating position, positioned at the third quadrant in a direction which is perpendicular to the fourth quadrant, and positioned at the second quadrant in a direction which is perpendicular to the first quadrant, and wherein the controller controls a rotation of the support unit so the second pattern is positioned at the fourth quadrant.

In an embodiment, the controller controls the heating unit so the laser irradiator is moved from the standby position to an irradiation position corresponding to the second pattern positioned at the fourth quadrant, and the laser light is irradiated to the second pattern from the irradiation position.

In an embodiment, the moving module moves the laser irradiator in a first direction which is horizontal to the ground, and a second direction which is perpendicular to the first direction and horizontal to the ground, and wherein the fourth quadrant is an area in which a sum of a movement amount in the first direction and a movement mount in the second direction of the laser irradiator is minimized from the standby position to the irradiation position.

In an embodiment, the mask treating apparatus further includes a standby port having the laser irradiator positioned at the standby position, and wherein a monitoring target having an origin matching a center of the laser irradiator when seen from above is provided on the standby port.

In an embodiment, the heating unit further includes a camera module in which a light irradiated from the laser irradiator acquires an image displayed on the monitoring target and transmits an acquired imaged to the controller.

In an embodiment, the controller derives a position information of the laser light from the image and calculates a movement amount of the laser irradiator from the standby position to the second pattern positioned at the irradiation position based on the position information.

In an embodiment, the controller derives a diameter information of the laser light from the image and acquires an information of the laser light irradiated from the laser irradiator based on the diameter information of the laser light.

In an embodiment, the first quadrant, the second quadrant, the third quadrant, and the fourth quadrant are sequentially positioned in a counter clockwise direction.

The inventive concept provides a mask treating apparatus. The mask treating apparatus includes a liquid supply unit for supplying a treating liquid to the mask supported on the support unit; and a container having a treating space for treating the mask and providing a recollecting path for recollecting the treating liquid, and wherein the support unit supports the mask at the treating space.

In an embodiment, the controller controls the heating unit so a critical dimension of the first pattern and a critical dimension of the second pattern is minimized by irradiating the laser light with respect to the second pattern.

In an embodiment, the first pattern provided to each cell is a monitoring pattern of an exposing pattern formed at a cell, and the second pattern is a condition setting pattern of the mask treating apparatus.

The inventive concept provides a substrate treating apparatus. The substrate treating apparatus includes a support unit for supporting and rotating a substrate having a pattern which is specific formed thereon; a heating unit for heating the pattern; and a controller for controlling the support unit and the heating unit, and wherein the controller controls the support unit to move the pattern to a heating position by rotating the substrate, and controls the heating unit so the heating unit moves to a standby position and a heating position.

In an embodiment, when a treating position is divided into four equal parts from a first quadrant to a fourth quadrant based on a center of the substrate, the heating unit is positioned at the fourth quadrant and the first quadrant in a direction linearly moving from a standby position to the treating position, positioned at the third quadrant in a direction which is perpendicular to the fourth quadrant, and positioned at the second quadrant in a direction which is perpendicular to the first quadrant, and the heating position is a position of the pattern when the pattern is positioned at the fourth quadrant.

In an embodiment, the heating unit moves in a first direction which is horizontal to the ground, and a second direction which is perpendicular to the first direction and horizontal to the ground, and wherein the fourth quadrant is an area in which a sum of a movement amount in the first direction and a movement mount in the second direction of the heating unit is minimized from the standby position to an irradiation position.

The inventive concept provides a substrate treating method for etching a substrate having a first pattern and a second pattern which is different from the first pattern formed thereon. The substrate treating method includes moving the second pattern to an irradiation position which is a position correcting step; supplying an etching liquid onto the substrate which is a liquid treating step; and irradiating a laser light to the second pattern which is moved to the irradiation position in a state of having the etching liquid remaining on the substrate which is a heating step, and wherein when a treating position is divided into four equal parts from a first quadrant to a fourth quadrant based on a center of the substrate, the irradiation position is a position corresponding to the second pattern positioned at the fourth quadrant when the heating unit is positioned at the fourth quadrant and the first quadrant in a direction linearly moving from a standby position to the treating position, positioned at the third quadrant in a direction which is perpendicular to the fourth quadrant, and positioned at the second quadrant in a direction which is perpendicular to the first quadrant.

In an embodiment, the fourth quadrant is an area which has a minimal movement of the heating unit from the standby position to the irradiation position.

In an embodiment, the position correcting step rotates the substrate to move the second pattern to the fourth quadrant.

In an embodiment, in the heating step the heating unit moves from the standby position to the irradiation position which corresponds to the second pattern which is positioned at the fourth quadrant, and a light is irradiated from the irradiation position to the second pattern.

In an embodiment, the substrate treating method further includes performing a process which minimizes a deviation between a critical dimension of the first pattern and a critical dimension of the second pattern by irradiating the laser light with respect to the second pattern.

In an embodiment, the first pattern is a monitoring pattern of an exposing pattern formed on the substrate, the second pattern is a condition setting pattern for treating the substrate.

According to an embodiment of the inventive concept, a substrate may be efficiently treated.

According to an embodiment of the inventive concept, a critical dimension of a pattern formed on a substrate may be made uniform.

According to an embodiment of the inventive concept, an etching on a specific pattern formed on a substrate may be performed precisely.

According to an embodiment of the inventive concept, a structure of a heating unit provided on a substrate may be minimized.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 illustrates a normal distribution of a critical dimension of a monitoring pattern and a critical dimension of an anchor pattern.

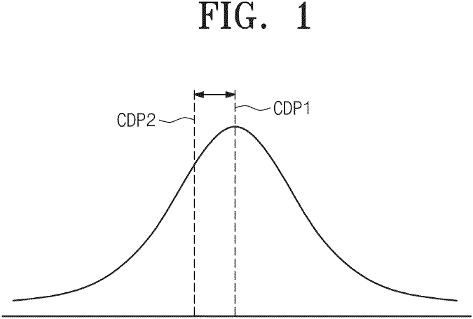

FIG. 2 is a plan view schematically illustrating a substrate treating apparatus according to an embodiment of the inventive concept.

FIG. 3 schematically illustrates a state of a substrate treated at a liquid treating chamber of FIG. 2.

FIG. 4 schematically illustrates an embodiment of the liquid treating chamber of FIG. 2.

FIG. 5 is a top view of the liquid treating chamber of FIG. 4.

FIG. 6 illustrates a body, a laser irradiation module, and a camera module of a heating unit of FIG. 4.

FIG. 7 is a top view of an image module of FIG. 6.

FIG. 8 illustrates an error checking unit and a support unit of the liquid treating chamber of FIG. 4.

FIG. 9 is a top view of the error checking unit of FIG. 8.

FIG. 10 is a flowchart illustrating a substrate treating method according to an embodiment of the inventive concept.

FIG. 11 illustrates a state in which the substrate treating apparatus checks an error between an irradiation position of a laser and a preset monitoring target position in a process preparing step of FIG. 10.

FIG. 12 and FIG. 13 illustrate a state of the substrate treating apparatus performing a position correcting step of FIG. 10.

FIG. 14 illustrates a state of the substrate treating apparatus performing a liquid treating step of FIG. 10.

FIG. 15 and FIG. 16 illustrate a state of the substrate treating apparatus performing a heating step of FIG. 10.

### DETAILED DESCRIPTION

The inventive concept may be variously modified and may have various forms, and specific embodiments thereof will be illustrated in the drawings and described in detail. However, the embodiments according to the concept of the inventive concept are not intended to limit the specific disclosed forms, and it should be understood that the present inventive concept includes all transforms, equivalents, and replacements included in the spirit and technical scope of the inventive concept. In a description of the inventive concept, a detailed description of related known technologies may be omitted when it may make the essence of the inventive concept unclear.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Hereinafter, embodiments of the inventive concept will be described in detail with reference to the accompanying drawings.

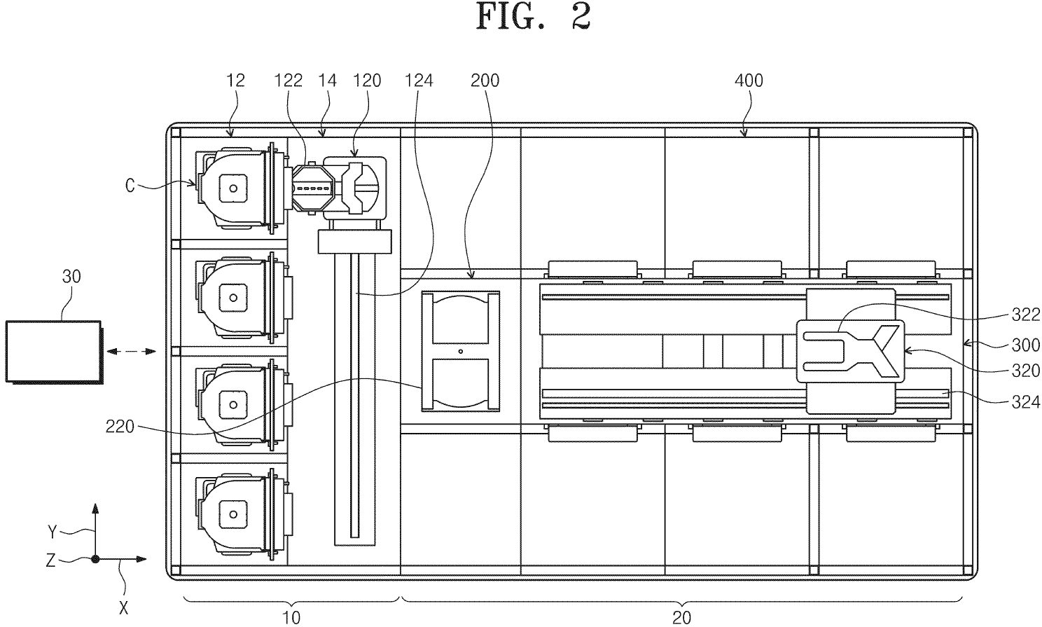

Hereinafter, an embodiment of the inventive concept will be described in detail with reference to FIG. 2 to FIG. 16. FIG. 2 is a plan view schematically illustrating a substrate treating apparatus according to an embodiment of the inventive concept. Referring to FIG. 2, the substrate treating apparatus includes an index module 10, a treating module 20, and a controller 30. According to an embodiment, when viewed from above, the index module 10 and the treating module 20 may be disposed along a direction. Hereinafter, a direction in which the index module 10 and the treating module 20 are disposed is defined as a first direction X, a direction perpendicular to the first direction X when viewed from above is defined as a second direction Y, and a direction perpendicular to a plane including both the first direction X and the second direction Y is defined as a third direction Z.

The index module 10 transfers a substrate M from a container C in which the substrate M is accommodated to the treating module 20 for treating the substrate M. The index module 10 stores a substrate M on which a predetermined treatment has been completed at the treating module 20 in the container C. A lengthwise direction of the index module 10 may be formed in the second direction Y. The index module 10 may have a load port 12 and an index frame 14.

The container C in which the substrate M is accommodated is seated on the load port 12. The load port 12 may be positioned on an opposite side of the treating module 20 with respect to the index frame 14. A plurality of load ports 12 may be provided, and the plurality of load ports 12 may be arranged in a line along the second direction Y. The number of load ports 12 may increase or decrease according to a process efficiency and foot print conditions, etc of the treating module 20.

As the container C, a sealing container such as a front opening unified pod (FOUP) may be used. The container C may be placed on the load port 12 by a transfer means (not shown) such as an overhead transfer, an overhead conveyor, or an automatic guided vehicle, or by an operator.

An index robot 120 and an index rail 124 may be provided at the index frame 14. The index robot 120 transfers the substrate M. The index robot 120 may transfer the substrate M between the index module 10 and the buffer unit 200 to be described later. The index robot 120 includes an index hand 122 on which the substrate M is placed. The substrate M may be placed on the index hand 122. The index hand 122 may be provided to be forwardly and backwardly movable, rotatable in the third direction Z, and movable along the third direction Z. A plurality of hands 122 may be provided to be spaced apart from each other in an up/down direction. The plurality of hands 122 may be forwardly and backwardly movable independently of each other.

The index rail 124 is provided in the index frame 14 with its lengthwise direction along the second direction Y. The index robot 120 may be placed on the index rail 124, and the index robot 120 may be movable along the index rail 124.

The controller 30 may control a substrate treating apparatus. The controller may comprise a process controller consisting of a microprocessor (computer) that executes a control of the substrate treating apparatus, a user interface such as a keyboard via which an operator inputs commands to manage the substrate treating apparatus, and a display showing the operation situation of the substrate treating apparatus, and a memory unit storing a treating recipe, i.e., a control program to execute treating processes of the substrate treating apparatus by controlling the process controller or a program to execute components of the substrate treating apparatus according to data and treating conditions. In addition, the user interface and the memory unit may be connected to the process controller. The treating recipe may be stored in a storage medium of the storage unit, and the storage medium may be a hard disk, a portable disk, such as a CD-ROM or a DVD, or a semiconductor memory, such as a flash memory.

The treating module 20 may include a buffer unit 200, a transfer chamber 300, and a liquid treating chamber 400. The buffer unit 200 provides a space in which a substrate M taken into the treating module 20 and a substrate M taken out of the treating module 20 temporarily remain. The transfer chamber 300 provides a space for transferring the substrate M between the buffer unit 200, the liquid treating chamber 400, and the drying chamber 500. The liquid treating chamber 400 supplies a liquid onto the substrate M to perform a liquid treatment process for treating the substrate M.

The buffer unit 200 may be disposed between the index frame 14 and the transfer chamber 300. The buffer unit 200 may be positioned at an end of the transfer chamber 300. A slot (not shown) in which the substrate M is placed is provided inside the buffer unit 200. A plurality of slots (not shown) may be provided to be spaced apart from each other in the third direction Z.

A front face and a rear face of the buffer unit 200 are opened. The front face is a surface facing the index module 10, and the rear face is a surface facing the transfer chamber 300. The index robot 120 may approach the buffer unit 200 through the front face, and the transfer robot 320 to be described later may approach the buffer unit 200 through the rear face.

The transfer chamber 300 may have a lengthwise direction provided in the first direction X. The liquid treating chamber 400 and the drying chamber 500 may be disposed on both sides of the transfer chamber 300. The liquid treating chamber 400 and the drying chamber 500 may be disposed at a side of the transfer chamber 300. The transfer chamber 300 and the liquid treating chamber 400 may be disposed along the second direction Y. The transfer chamber 300 and the drying chamber 500 may be disposed along the second direction Y.

According to an embodiment, liquid treating chambers 400 may be disposed on both sides of the transfer chamber 300. The liquid treating chambers 400 may be provided in an arrangement of AX B (where A and B are natural numbers greater than 1 or 1 respectively) along the first direction X and the third direction Z respectively at aside of the transfer chamber 300.

The transfer chamber 300 includes a transfer robot 320 and a transfer rail 340. The transfer robot 320 transfers the substrate M. The transfer robot 320 transfers the substrate M between the buffer unit 200, the liquid treating chamber 400, and the drying chamber 500. The transfer robot 320 includes a transfer hand 322 on which the substrate M is placed. The substrate M may be placed on the transfer hand 322. The transfer hand 322 may be provided to be forwardly and backwardly movable, to be rotatable around the third direction Z, and movable along the third direction Z. A plurality of hands 322 are provided to be spaced apart from each other in the up/down direction, and the plurality of hands 322 may be forwardly and backwardly movable independently of each other.

The transfer rail 340 may be provided in the transfer chamber 300 along a lengthwise direction of the transfer chamber 300. In an embodiment, the lengthwise direction of the transfer rail 340 may be provided along the first direction X. The transfer robot 320 may be placed on the transfer rail 340 and the transfer robot 320 may be movable on the transfer rail 340.

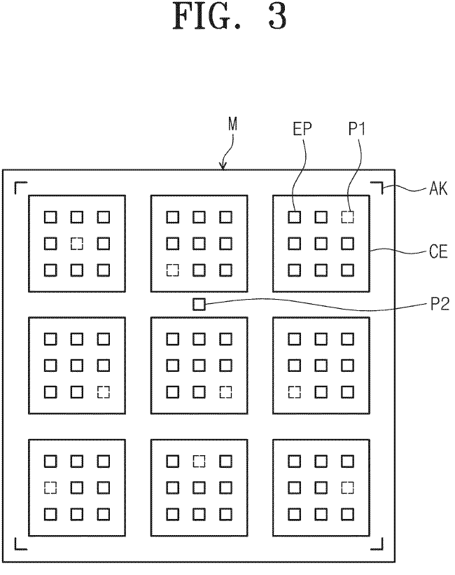

Hereinafter, a substrate M treated in the liquid treating chamber 400 will be described in detail. FIG. 3 schematically illustrates a state of the substrate treated in the liquid treating chamber of FIG. 2.

Referring to FIG. 3, an object to be treated in the liquid treating chamber 400 may be any one of a wafer, a glass, and a photomask. For example, the substrate M treated in the liquid treating chamber 400 may be a photo mask, which is a ‘frame’ used in an exposing process.

The substrate M may have a rectangular form. The substrate M may be a photo mask that is a ‘frame’ used in the exposing process. At least one reference mark AK may be marked on the substrate M. For example, a plurality of reference marks AK may be formed in each corner region of the substrate M. The reference mark AK may be a mark called an align key used when aligning the substrate M. Also, the reference mark AK may be a mark used to derive a position of the substrate M. For example, an image module 470 to be described later may acquire an image by imaging the reference mark AK and transmit the acquired image to the controller 30. The controller 30 then may analyze the image including the reference mark AK to detect an accurate position of the substrate M. In addition, the reference mark AK may be used to determine a position of the substrate M when the substrate M is transferred.

A cell CE may be formed on the substrate M. At least one cell CE, for example, a plurality of cells CE may be formed. A plurality of patterns may be formed at each cell CE. The patterns formed at each cell CE may be defined as one pattern group. Patterns formed at the cell CE may include an exposing pattern EP and a first pattern P1. A second pattern P2 may be proved in a region outside the cell region where the plurality of cells care formed.

The exposing pattern EP may be used to form an actual pattern on the substrate M. The first pattern P1 may be a single-cell representative pattern representing exposing patterns EP in one cell CE. In addition, when the plurality of cells CE are provided, the first pattern is provided in each cell, thereby a plurality of first patterns P1 may be provided. In an embodiment, each of the plurality of cells CE may be provided with single first pattern P1. However, the inventive concept is not limited thereto, and the plurality of first patterns P1 may be formed in one cell CE. The first pattern P1 may have a form in which portions of each exposing pattern EP are combined. The first pattern P1 may be referred to as a monitoring pattern. An average value of critical dimension of the plurality of first patterns P1 may be referred to as a critical dimension monitoring macro.

When an operator inspects the first pattern P1 through a scanning electron microscope (SEM), it is possible to estimate whether a form of the exposing patterns EPs formed in one cell CE are good or bad. Accordingly, the first pattern P1 may serve as an inspection pattern to inspect the exposing patters EPs. Also, unlike the above-described example, the first pattern P1 may be any one of the exposing patterns EPs used in an actual exposing process. In addition, the first pattern P1 may be serve as not only inspection pattern to inspect the exposing patterns but also exposing pattern used in the actual exposing.

The second pattern P2 may be an entire-cell representative pattern representing exposing patterns EP on whole cells of the substrate M. For example, the second pattern P2 may have a form in which portions of each of the first patterns P1 are combined.

When the operator inspects the second pattern P2 through the scanning electron microscope (SEM), it is possible to estimate whether a form of the exposing patterns EPs formed on one substrate M are good or bad. Accordingly, the second pattern P2 may serve an inspection pattern. In addition, the second pattern P2 may be an inspection pattern that is not used in an actual exposing process. The second pattern P2 may be a pattern for setting a process condition of an exposing apparatus. The second pattern P2 may be referred to as an anchor pattern.

Hereinafter, the substrate treating apparatus provided to the liquid treating chamber 400 will be described in detail. Hereinafter, a treating process performed while the liquid treating chamber 400 performs a fine critical dimension correction (FCC) process during a process of manufacturing a mask for an exposing process will be described as an example.

A substrate M to be taken in and treated at the liquid treating chamber 400 may be a substrate M on which a pre-treatment has been performed. A critical dimension of the first pattern P1 and a critical dimension of the second pattern P2 of the substrate M to be taken into the liquid treating chamber 400 may be different from each other. For example, the critical dimension of the first pattern P1 may be greater than the critical dimension of the second pattern P2. In on embodiment, the critical dimension of the first pattern P1 may have a first width (e.g., 69 nm). The critical dimension of the second pattern P2 may have a second width (e.g., 68.5 nm).

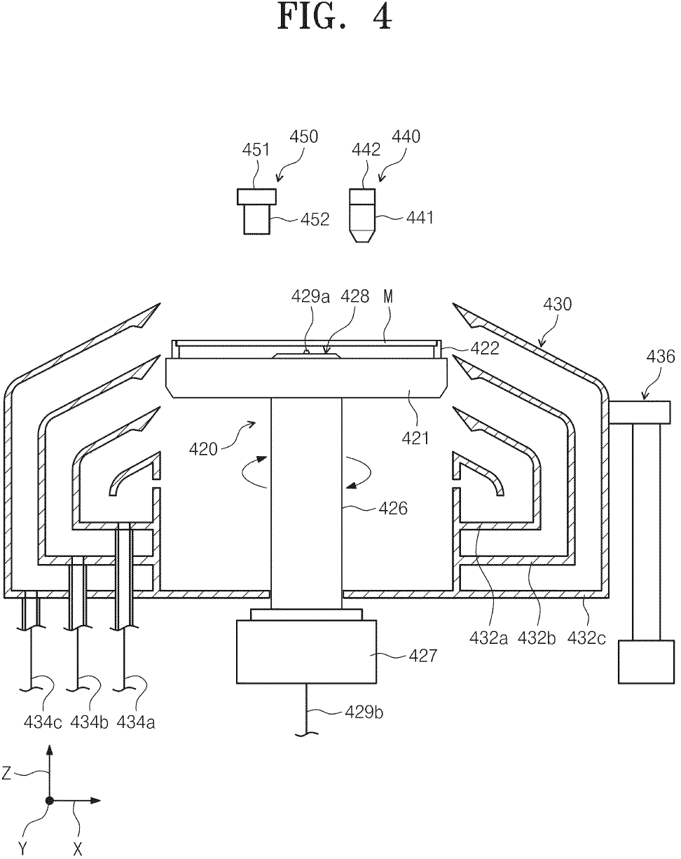

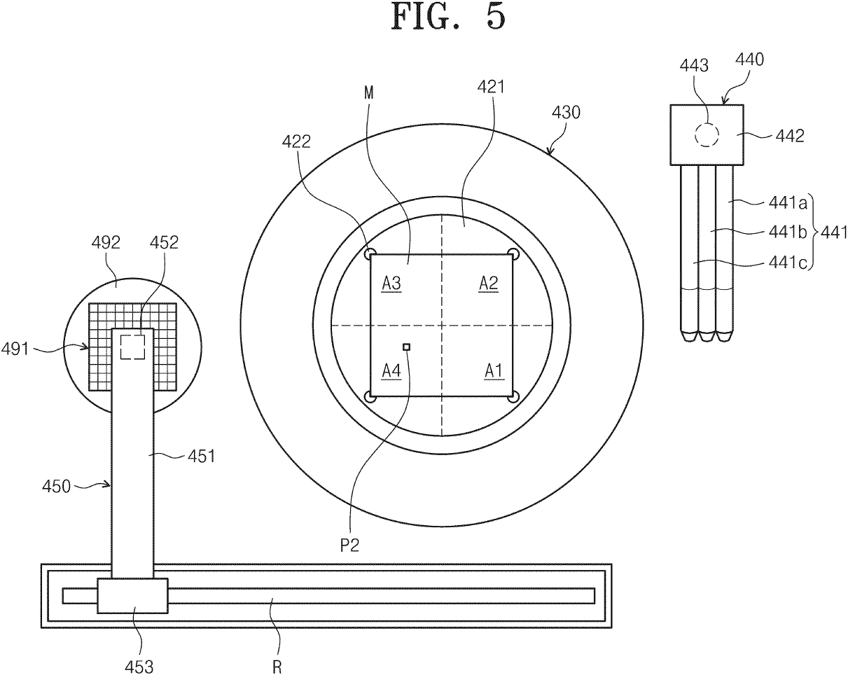

FIG. 4 schematically illustrates an embodiment of the liquid treating chamber of FIG. 2. FIG. 5 is a top view of the liquid treating chamber of FIG. 4. Referring to FIG. 4 and FIG. 5, the liquid treating chamber 400 may include a housing (not shown), a support unit 420, a treating container 430, a liquid supply unit 440, and a heating unit 450.

The housing (not shown) has an inner space. The housing (not shown) may have an inner space provided with a treating container 430. The housing (not shown) may have an inner space in which the liquid supply unit 440 and the heating unit 450 are provided. The housing (not shown) may be provided with a gateway (not shown) through which the substrate M may be taken in and taken out. An inner wall surface of the housing (not shown) may be coated with a material having a high corrosion resistance to a chemical supplied by the liquid supply unit 440.

An exhaust hole (not shown) may be formed on a bottom surface of the housing (not shown). The exhaust hole (not shown) may be connected to an exhaust member such as a pump capable of exhausting an inner space. Accordingly, a fume or the like that may be generated at the inner space may be exhausted to an outside of the housing (not shown) through the exhaust hole (not shown).

The support unit 420 may support the substrate M in a treating space of the treating container 430 to be described later. The support unit 420 may support the substrate M. The support unit 420 may rotate the substrate M. The support unit 420 may include a chuck 421, a support pin 422, a support shaft 426, and a driving member 427.

The chuck 421 may have a plate form having a constant thickness. The chuck 421 may have a top surface provided in a generally circular form when viewed from above. The top surface of the chuck 421 may be provided to have an area larger than that of the substrate M. The support pin 422 may be installed on the chuck 421.

The support pin 422 may support the substrate M. A plurality of support pins 422 are provide along a circumferential direction of the top side chuck 421, thereby viewed from above, the support pins 422 may have a substantially circular form. When viewed from above, the support pin 422 may have a stepped portion to support the substrate M. The stepped portion of the support pin 422 may have a first surface (lower surface) and a second surface(side surface). In an embodiment, the first surface may support back-side (bottom side) surface at edge region of the substrate M. The second surface may support side surface of the substrate M so as to limit a lateral movement of the substrate M when the substrate M is rotated. At least one support pin 422 may be provided. In an embodiment, a plurality of support pins 422 may be provided. The support pins 422 may be provided in a number corresponding to the number of corners of the substrate M having a rectangular form. The support pin 422 may support the back-side(bottom surface) of the substrate M to be spaced apart from a top surface of the chuck 421.

The support shaft 426 may be coupled to the chuck 421. The support shaft 426 may be positioned below the chuck 421. The support shaft 426 may be a hollow shaft. The support shaft 426 may be rotated by the driving member 427. The driving member 427 may be a hollow motor. When the driving member 427 rotates the support shaft 426, the chuck 421 coupled to the support shaft 426 may rotate. A substrate M placed on the support pin 422 installed on the chuck 421 may be rotated together with a rotation of the chuck 421.

The treating container 430 has a treating space with an open top. The treating container 430 may have a cylindrical form with an open top. The substrate M may be liquid-treated and heat-treated in the treating space. The treating container 430 can prevent the treating liquid supplied to the substrate M from being scattered to the housing (not shown), the liquid supply unit 440, and the heating unit 450.

The treating container 430 may have a plurality of recollecting containers 432a, 432b, and 432c. Each of the recollecting containers 432a, 432b, and 432c may separately recollect different liquids from each other among liquids used for treating the substrate M. Each of the recollecting containers 432a, 432b, and 432c may have a recollecting space for recollecting a liquid used for treating the substrate M. Each of the recollecting containers 432a, 432b, and 432c may be provided in an annular ring form surrounding the support unit 420. When the liquid treatment process is performed, a liquid scattered by a rotation of the substrate M is introduced into the recollecting space through an inlet, which is a space formed between the recollecting containers 432a, 432b, and 432c, respectively. The different types of treating liquids may be introduced into each of the recollecting containers 432a, 432b, and 432c.

According to an embodiment, the treating container 430 may have a first recollecting container 432a, a second recollecting container 432b, and a third recollecting container 432c. The first recollecting container 432a may be provided in an annular ring form surrounding the support unit 420. The second recollecting container 432b may be provided in an annular ring form surrounding the first recollecting container 432a. The third recollecting container 432c may be provided in an annular ring form surrounding the second recollecting container 432b.

To each of the recollecting containers 432a, 432b, 432c, recollecting lines 434a, 434b, 434c extending vertically in a bottom direction of a respective bottom surface can be connected. Each of the recollecting lines 434a, 434b, 434c may discharge a treating liquid introduced through each of the recollecting containers 432a, 432b, 432c. A discharged treating liquid may be reused through an outer treating liquid regeneration system (not shown).

The treating container 430 may be coupled to a lifting/lowering member 436. The lifting/lowering member 436 may change a position of the treating container 430 along the third direction Z. The lifting/lowering member 436 may be a driving device for moving the treating container 430 in the up/down direction. The lifting/lowering member 436 may move the treating container 430 in an upward direction while a liquid treatment and/or a heat treatment are performed on the substrate M. The lifting/lowering member 436 may move the treating container 430 in a downward direction when the substrate M is taken into the inner space or the substrate M is taken out of the inner space.

The liquid supply unit 440 may supply a liquid to the substrate M. The liquid supply unit 440 may supply a treating liquid for liquid treating the substrate M. The liquid supply unit 440 may supply the treating liquid to a substrate M supported by the support unit 420. In an embodiment, the liquid supply unit 440 may supply the treating liquid to a substrate M having a first pattern formed within a plurality of cells CE and a second pattern P2 formed outside a region at which the cells CE are formed.

The treating liquid may be an etching liquid or a rinsing liquid. The etching liquid may be a chemical. The etching liquid may etch a pattern formed on the substrate M. The etching liquid may also be referred to as an etching liquid. The etching liquid may be a liquid containing a mixed solution in which an ammonia, a water, and additives are mixed and a hydrogen peroxide is included. The rinsing liquid may clean the substrate M. The rinsing liquid may be provided as a known chemical liquid.

Referring to FIG. 5, the liquid supply unit 440 may include a nozzle 441, a fixing body 442, a rotation shaft 443, and a rotation member 444. The nozzle 441 may supply the treating liquid to the substrate M supported by the support unit 420. An end of the nozzle 441 may be connected to the fixing body 442, and another end thereof may extend in a direction from the fixing body 442 toward the substrate M. The nozzle 411 may extend from the fixing body 442 in the first direction X.

The nozzle 411 may include a first nozzle 411a, a second nozzle 411b, and a third nozzle 411c. Any one of the first nozzle 411a, the second nozzle 411b, or the third nozzle 411c may supply a chemical C among the above-described treating liquids. In addition, another one of the first nozzle 411a, the second nozzle 411b, and the third nozzle 411c may supply the rinsing liquid R among the aforementioned treating liquids. The last one of the first nozzle 411a, the second nozzle 411b, or the third nozzle 411c may supply a different kind of chemical C which is different from a chemical C supplied by the another one of the first nozzle 411a, the second nozzle 411b, or the third nozzle 411c.

A body 442 may fix and support the nozzle 441. The body 442 may be connected to the rotation shaft 443 rotated in the third direction Z by the rotation member 444. When the rotation member 444 rotates the rotation shaft 443, the body 442 may rotate around the third direction Z. Accordingly, an outlet of the nozzle 441 may move between a liquid supply position which is a position where the treating liquid is supplied to the substrate M and a standby position which is a position where the treating liquid is not supplied to the substrate M.

The heating unit 450 may heat the substrate M. The heating unit 450 may heat a partial region of the substrate M. The heating unit 450 may heat a specific region of the substrate M. The heating unit 450 may heat the substrate M on which a liquid film is formed by supplying the chemical C. The heating unit 450 may heat a pattern formed on the substrate M. The heating unit 450 may heat some of the patterns formed on the substrate M. The heating unit 450 may heat any one of the first pattern P1 or the second pattern P2. For example, the heating unit 450 may heat the second pattern P2 among the first pattern P1 and the second pattern P2. In an embodiment, the heating unit 450 may heat the second pattern P2 by irradiating a laser light L with the second pattern P2.

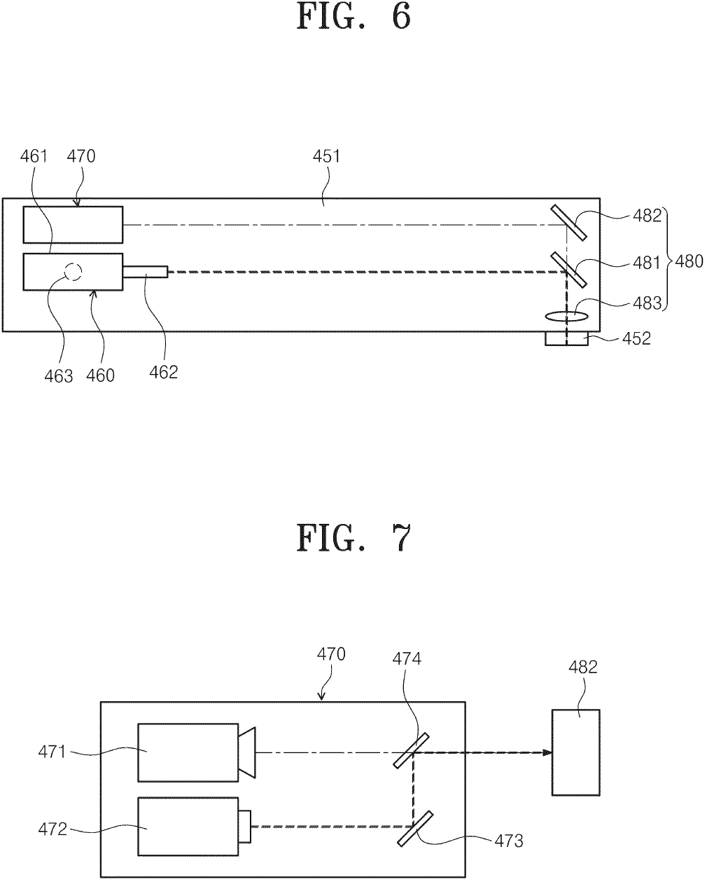

FIG. 6 illustrates a body, a laser irradiation module, and a camera module of the heating unit of FIG. 4. Referring to FIG. 6, the heating unit 450 may include a body 451, a moving module, a laser irradiation module 460, and a camera module. The moving module may include a driver 453, and a guide rail R. The camera module may include an image module 470 and an optical module 480.

The body 451 may be a container having an installation space therein. The body 451 may be provided with a laser irradiation module 460 to be described later, an image module 470 and an optical module 480. The body 451 may include a laser irradiator 452. The laser light L emitted by the laser irradiation module 460 to be described later may be emitted to the substrate M through the laser irradiator 452. In addition, a light irradiated by the illumination member 472 to be described later may be provided through the laser irradiator 452. In addition, an image imaging of an image acquisition member 471 to be described later may be performed through the laser irradiator 452.

The driver 453 may be a motor. In an embodiment, the driver 453 may be provided as a linear motor. The driver 453 may be provided as a known motor that provides a driving force. The driver 453 may be connected to the body 451. The driver 453 may move the body 451 in transverse direction which is orthogonal to longitudinal direction of the body 451. The driver 453 may move the body 451 along the first direction X and/or the second direction Y. The driver 453 may move the laser irradiator 452 to be described later between a standby position where the laser irradiator 452 does not perform a process and a heating position where the laser irradiator 452 irradiates the laser light L on the substrate M. Also, the driver 453 may move the body 451 in third direction Z.

The guide rail R may have its lengthwise direction along the first direction. The driver 453 is positioned on the guide rail R. The driver 453 positioned on the guide rail R may be moved in the first direction X along the guide rail R. The body 451 connected to the driver 453 may be moved in the first direction X. Accordingly, the laser irradiator 452 provided at one end of the body 451 opposite the driver 453 may be moved in the first direction X.

The second driver 455 may be any one of known devices for generating a power such as a motor, a pneumatic cylinder, a hydraulic cylinder, or a solenoid. The second driver 455 may be connected to the body 451. The second driver 455 may be connected to a shaft (not shown). The shaft (not shown) may move the body 451 in the second direction Y by receiving a driving force generated by the second driver 455. Accordingly, the laser irradiator 452 may be moved in the second direction Y. The second driver 455 may move the laser irradiator 452 between a standby position where the laser irradiator 452 to be described later does not perform a process and a heating position where the laser irradiator 452 irradiates the laser light L on the substrate M.

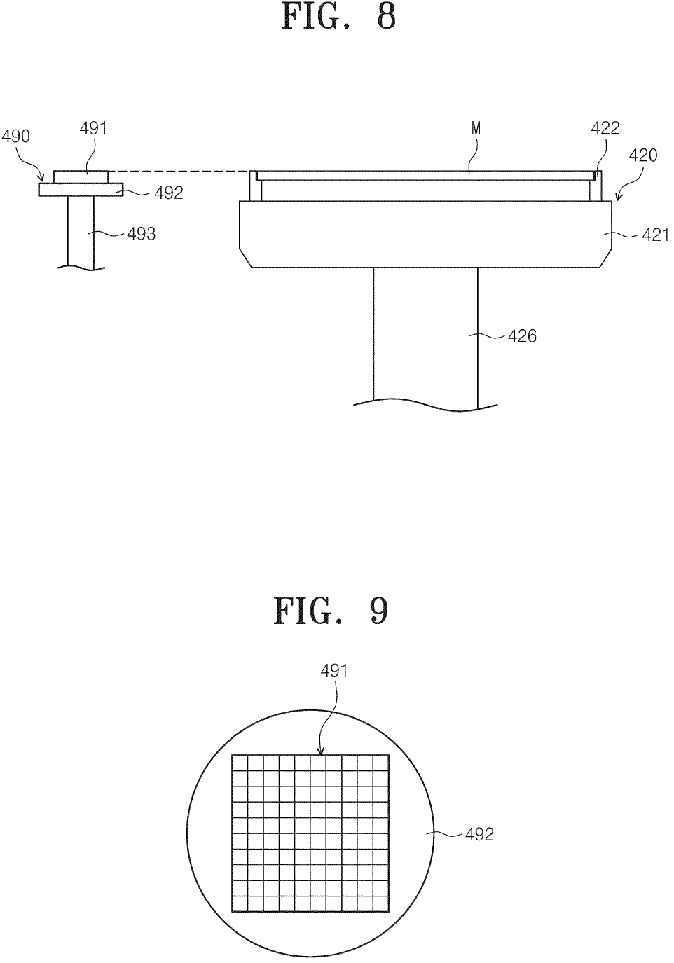

FIG. 6 illustrates a body, a laser irradiation module, and a camera module of the heating unit of FIG. 4. FIG. 7 is a top view of the image module of FIG. 6. Referring to FIG. 6 and FIG. 7, a laser irradiation module 460 may be installed on the body 451. A camera module may be installed on the body 451.

The laser irradiation module 460 may include a laser irradiation unit 461, a beam expander 462, and a tilting member 463. The laser irradiation unit 461 may irradiate the laser light L. The laser irradiation unit 461 may emit the laser light L having a straightness. A form/profile of the laser light L emitted by the laser irradiation unit 461 may be adjusted by the beam expander 462. For example, a diameter of the laser light L emitted by the laser irradiation unit 461 may be changed by the beam expander 462. The diameter of the laser light L emitted by the laser irradiation unit 461 may be expanded or reduced by the beam expander 462.

The tilting member 463 may tilt an irradiation direction of the laser light L emitted by the laser irradiation unit 461. For example, the tilting member 463 may rotate the laser irradiation unit 461 based on an axis to tilt the irradiation direction of the laser light L irradiated by the laser irradiation unit 461. The tilting member 463 may include a motor.

The camera module may include an image module 470 and an optical module 480. The image module 470 may monitor the laser light L emitted by the laser irradiation unit 461. The image module 470 may include an image acquisition member 471, an illumination member 472, a first reflective plate 473, and a second reflective plate 474. The image acquisition member 471 may acquire an image of the substrate M and/or the monitoring target 491 of the error checking unit 490 to be described later. The image acquisition member 471 may be a camera. The image acquisition member 471 may acquire an image including a point at which the laser light L irradiated by the laser irradiation unit 461 is irradiated. The image module 470 may transmit an image acquired by the image acquisition member 471 to the controller 30. The image module 470 may acquire an image displayed on the monitoring target 491 to be described later by the laser light L emitted from the laser irradiator 452, and transmit the acquired image to the controller 30.

The illumination member 472 may provide a light so that an image acquisition of the image acquisition member 471 may be easily performed. A light provided by the illumination member 472 may be sequentially reflected along the first reflective plate 473 and the second reflective plate 474.

The optical module 480 may have a coaxial of an irradiation direction of the laser light L irradiated by the laser irradiation unit 461, an imaging direction in which the image acquisition member 471 acquires an image, and an irradiation direction of a light provided by the illumination member 472 when viewed from above. The illumination member 472 may transmit a light to a region to which the laser light L is irradiated by the optical module 480. In addition, the image acquisition member 471 may acquire an image such as an image/photo for a region to which the laser light L is irradiated in real time. The optical module 480 may include a first reflective member 481, a second reflective member 482, and a lens 483.

The first reflective member 481 may change an irradiation direction of the laser light L emitted by the laser irradiation unit 461. For example, the first reflective member 481 may change the irradiation direction of the laser light L irradiated in a horizontal direction to a vertical downward direction. In addition, a laser light L refracted by the first reflective member 481 may sequentially pass through the lens 483 and the laser irradiator 452, and may be transmitted to a substrate M to be treated or to a monitoring target 491 to be described later.

The second reflective member 482 may change the imaging direction of the image acquisition member 471. For example, the second reflective member 482 may change the imaging direction of the image acquisition member 471 in the horizontal direction to the vertical downward direction. In addition, the second reflective member 482 may change the irradiation direction of light of the illumination member 472 sequentially transmitted through the first reflective plate 473 and the second reflective plate 474 from the horizontal direction to the vertical downward direction.

In addition, the first reflective member 481 and the second reflective member 482 may be provided at the same position when viewed from above. The first reflective member 481 and the second reflective member 422 are may be disposed such that the imaging direction and the laser pathway coincide. In addition, the second reflective member 482 may be disposed above the first reflective member 481. In addition, the first reflective member 481 and the second reflective member 482 may be tilted at the same angle.

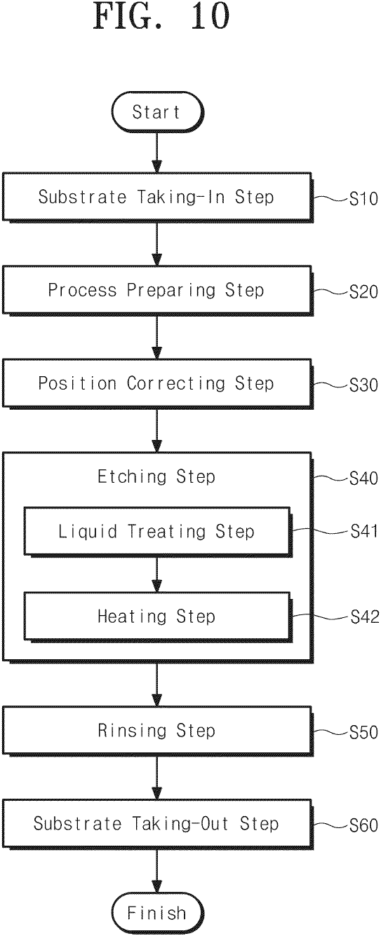

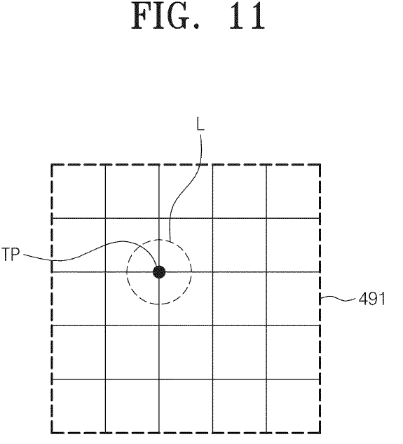

FIG. 8 illustrates an error checking unit of the liquid treating chamber and a support unit of FIG. 4. FIG. 9 is a top view of the error checking unit of FIG. 8. Referring to FIG. 8 and FIG. 9, the error checking unit 490 can check whether an error occurs between an irradiation position of the laser light L and a preset target position TP. For example, the error checking unit 490 may be provided in an inner space of the housing (not shown). Also, the error checking unit 490 may be installed in region below the laser irradiator 452 when the laser irradiator 452 is in an above-described standby position. The error checking unit 490 may include a monitoring target 491, a plate 492, and a support frame 493. The plate 492 and the support frame 493 may be provided as a standby port providing a space in which the laser irradiator 452 stands by. The standby port is positioned at a standby position where the laser irradiator 452 stands by. Accordingly, the plate 492 and the support frame 493 may be positioned at the standby position when viewed from above.

The monitoring target 491 may be referred to as a global coordinate system. The preset target position TP may be marked on the monitoring target 491. In addition, the monitoring target 491 may include a scale to check an error between the target position TP and the irradiation position to which the laser light L is irradiated. The monitoring target 491 may have an origin corresponding to a center of the laser irradiator 452 positioned above the standby port. The monitoring target 491 may have an origin corresponding to a center of a light irradiated from the laser irradiator 452 positioned above the standby port.

The monitoring target 491 may be installed on the plate 492. The plate 492 may be supported by a support frame 493. A height of the monitoring target 491 determined by the plate 492 and the support frame 493 may be the same height as a substrate M supported by the support unit 420. For example, a height from a bottom surface of the housing (not shown) to a top surface of the monitoring target 491 may be the same as a height from the bottom surface of the housing (not shown) to a top surface of the substrate M supported by the support unit 420. This is to match a height of the laser irradiator 452 when checking an error using the error checking unit 490, and the height of the laser irradiator 452 when heating the substrate M.

When an irradiation direction of the laser light L irradiated by the laser irradiation unit 461 is slightly distorted with respect to a third direction Z, the irradiation position of the laser light L may vary according to a height of the laser irradiation unit 452, and thus the monitoring target 491 may be provided at the same height as the substrate M supported by the support unit 420.

Hereinafter, a substrate treating method according to an embodiment of the inventive concept will be described in detail. The substrate treating method described below may be performed by the liquid treating chamber 400 described above. Also, the controller 30 can control components of the liquid treating chamber 400 so that the liquid treating chamber 400 can perform the substrate treating method described below. For example, the controller 30 may generate a control signal for controlling at least one of a support unit 420, a lifting/lowering member 436, a liquid supply unit 440, and a heating unit 450 so that the components of the liquid treating chamber 400 may perform the substrate treating method described below.

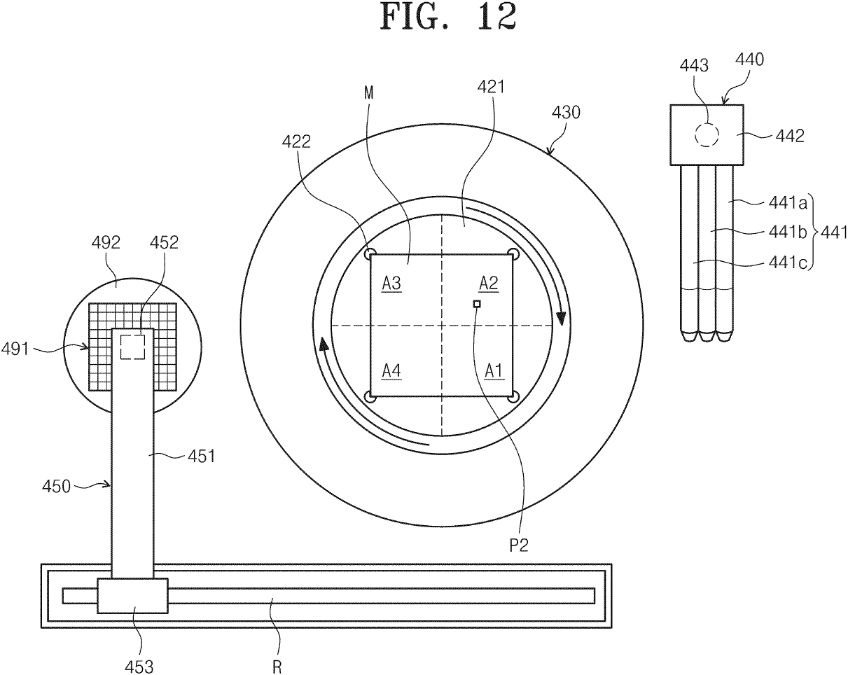

FIG. 10 is a flowchart illustrating a substrate treating method according to an embodiment of the inventive concept. Referring to FIG. 10, the substrate treating method according to an embodiment of the inventive concept may include a substrate taking-in step S10, a process preparing step S20, a position correcting step S30, an etching step S40, a rinsing step S50, and a substrate taking-out step S60.

In the substrate taking-in step S10, a door may open a taking-in/out port formed at the housing (not shown). In addition, in the substrate taking-in step S10, the transfer robot 320 may seat a substrate M on a support unit 420. While the transfer robot 320 seats the substrate M on the support unit 420, a lifting/lowering member 436 may lower a position of a treating container 430.

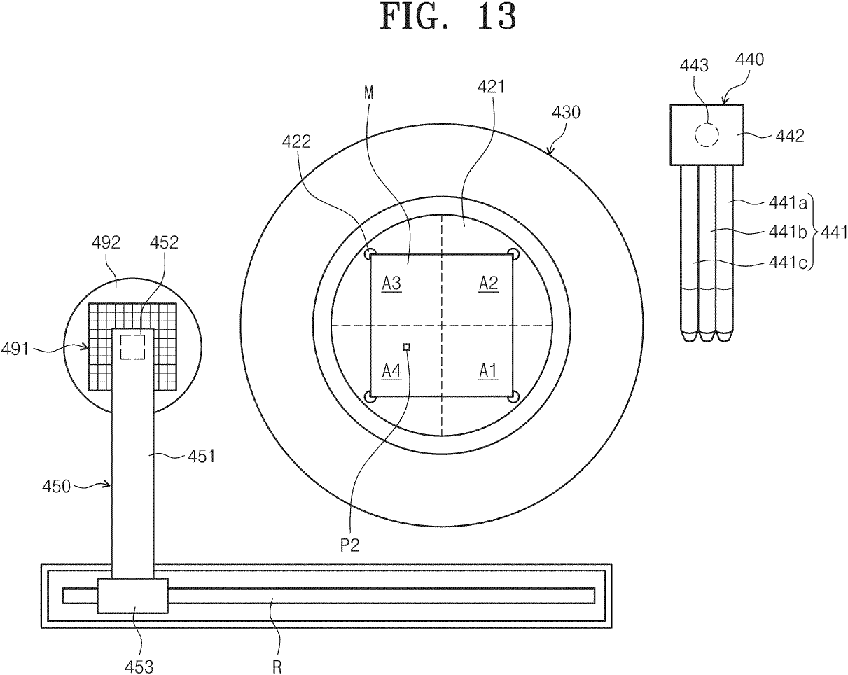

FIG. 11 illustrates a state in which a substrate treating apparatus checks an error between an irradiation position of a laser and a preset target position at a process preparing step of FIG. 10. Referring to FIG. 11, the process preparing step S20 may be performed after a taking-in of a substrate M is completed. In the process preparing step S20, it may be confirmed whether the substrate M is accurately seated on a support pin 422. In the process preparing step S20, a position of the substrate M may be confirmed. In the process preparing step S20, it may be confirmed whether an error occurs at the irradiation position of a laser light L irradiated to the substrate M. For example, in the process preparing step S20, a laser irradiation module 460 may irradiate a test laser light L to a monitoring target 491 of the error checking unit 490.

An image of a laser light L projected on the monitoring target 491 may be acquired by an image acquisition member 471. A location information at a standby position of the laser irradiation module 460 may be derived from an acquired image acquired by the image acquisition member 471. A location information of the laser light L emitted from a laser irradiator 452 may be derived from the acquired image.

In an embodiment, when the laser light L emitted from the laser irradiator 452 is not located at an origin of the monitoring target 491, it may be determined that a distortion has occurred at the laser irradiation unit 461. When the laser is irradiated to the preset target position TP of the monitoring target 491, it is determined that a distortion has not occurred at the laser irradiation unit 461, and the following position correcting step S30 may be performed.

In addition, a sum of the movement amount of the laser irradiator 542 from the above-described standby position to a specific pattern positioned at a heating position irradiating the laser light L may be calculated based on a position information of the test laser light L calculated from the acquired image. In an embodiment, the movement amount of the laser irradiator 542 in a first direction X and the movement amount in the second direction Y from the standby position to the second pattern P2 positioned at the heating position may be calculated, respectively. When the movement amount of the laser irradiator 542 in the first direction X or the movement amount in the second direction Y is not the same as a preset value of the movement amount, it may be determined that a position of the laser irradiator 542 is distorted.

In addition, the diameter information of the test laser light L calculated from the acquired image may be derived. Based on the derived diameter information of the test laser light L, information of the laser light L irradiated from the laser irradiator 542 may be acquired. For example, when an acquired image of the laser light L is outside the diameter range of the predetermined range, it may be determined that a problem has occurred in the beam expander 462.

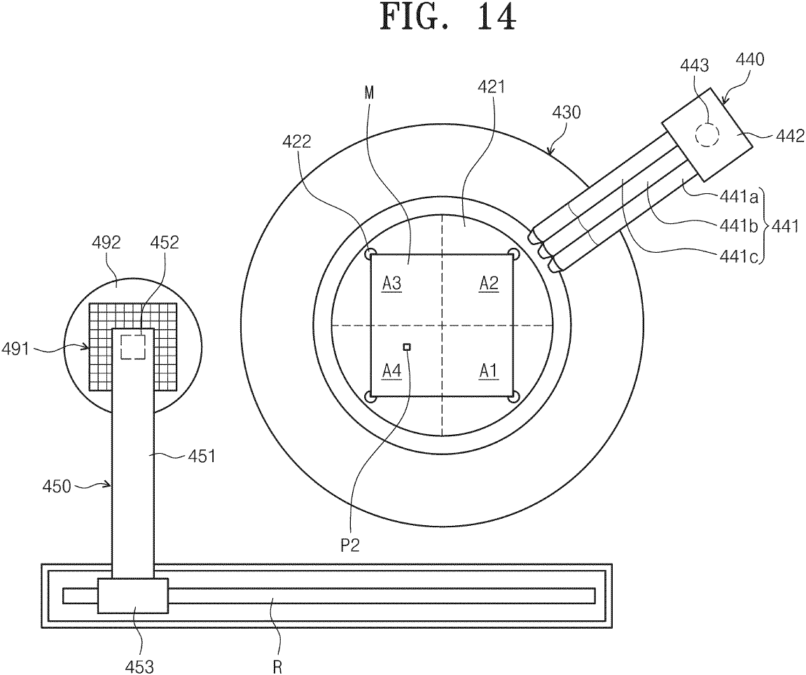

FIG. 12 and FIG. 13 are views illustrating a state of a substrate treating apparatus for performing a position correcting step of FIG. 10. Referring to FIG. 12 and FIG. 13, the position correcting step S30 can move a specific pattern formed on a substrate M to a heating position at which a laser light L is irradiated. The heating position may be one region among the equally divided four regions of which the substrate M supported on the support unit 420. In an embodiment, when a treating position is divided into four equal parts for treating the substrate supported on the support unit, the heating position of the laser irradiator 452 may be positioned in a first direction X and/or a second direction Y of a movement from a standby position to a treating position sequentially at a fourth quadrant A4 and a first quadrant A1, and may be positioned within the fourth quadrant A4 when a third quadrant A3 is positioned in a direction perpendicular to the fourth quadrant A4, and may be positioned within the fourth quadrant when a second quadrant A2 is positioned in an upward direction perpendicular to the first quadrant. That is, the heating position may be an area in which an amount of movement of the laser irradiator 452 is smallest when the laser irradiator 452 moves from the standby position to the treating position.

In the position correcting step S30, a second pattern P2 among of a first pattern P1 and a second pattern P2 formed on a substrate M moves to the heating position. In the position correcting step S30, the support unit 420 is rotated so the second pattern P2 is positioned within the fourth quadrant A4. In an embodiment, when the second pattern P2 is positioned within the first quadrant A1, the support unit 420 rotates clockwise to position the second pattern P2 within the fourth quadrant A4. In another embodiment, when the second pattern P2 is positioned within the third quadrant A3, the support unit 420 rotates counterclockwise to position the second pattern P2 within the fourth quadrant A4.

In an etching step S40, an etching on a pattern formed on the substrate M may be performed. In the etching step S40, an etching with respect to the pattern formed on the substrate M can be carried out so that a critical dimension of the first pattern P1 and a critical dimension of the second pattern P2 coincide with each other. The etching step S40 may be a critical dimension correction process for correcting a critical dimension difference between the first pattern P1 and the second pattern P2 described above. The etching step S40 may include a liquid treating step S41 and a heating step S42.

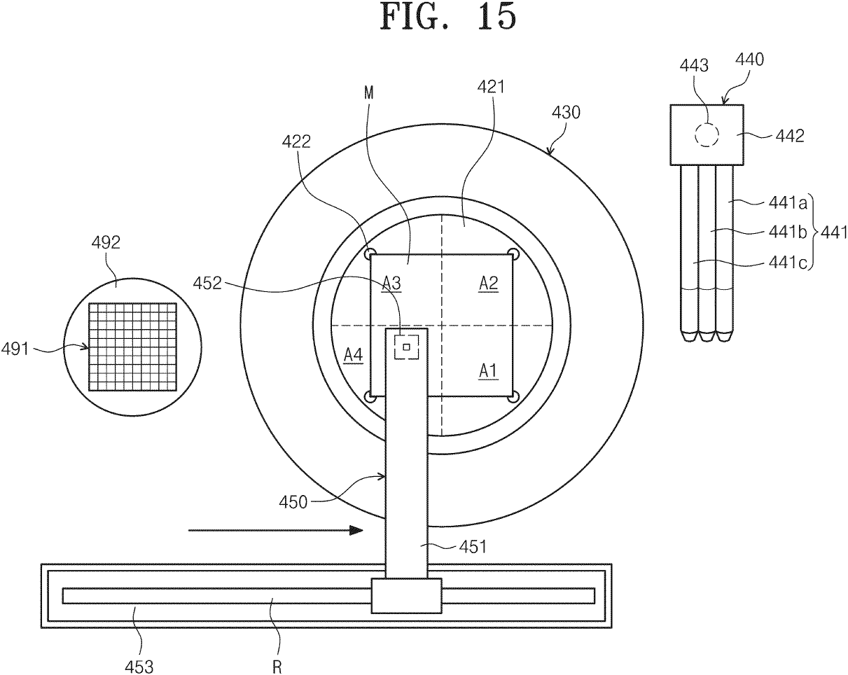

FIG. 14 illustrates a state of a substrate treating apparatus for performing a liquid treating step of FIG. 10. Referring to FIG. 14, the liquid treating step S41 may be a step in which a liquid supply unit 440 supplies an etchant which is a chemical C to a substrate M. In the liquid treating step S41, a support unit 420 may rotate the substrate M. However, the inventive concept is not limited thereto, and in the liquid treating step S41, the support unit 420 may not rotate the substrate M. An amount of the chemical C supplied at the liquid treating step S41 may be supplied enough to form a puddle of the chemical C supplied onto the substrate M. For example, the amount of the chemical C supplied at the liquid treating step S41 may cover an entire top surface of the substrate M, but may be supplied to a degree that the amount of the chemical C does not flow down or is not large even when if chemical C flows down from the substrate M. If necessary, the etchant may be supplied to an entire top surface of the substrate M while a nozzle 441 changes its position. After the liquid supply unit 440 supplies the chemical C to the substrate M, the support unit 420 may not rotate. The support unit 420 may stop to form a puddle of the chemical C supplied onto the substrate M.

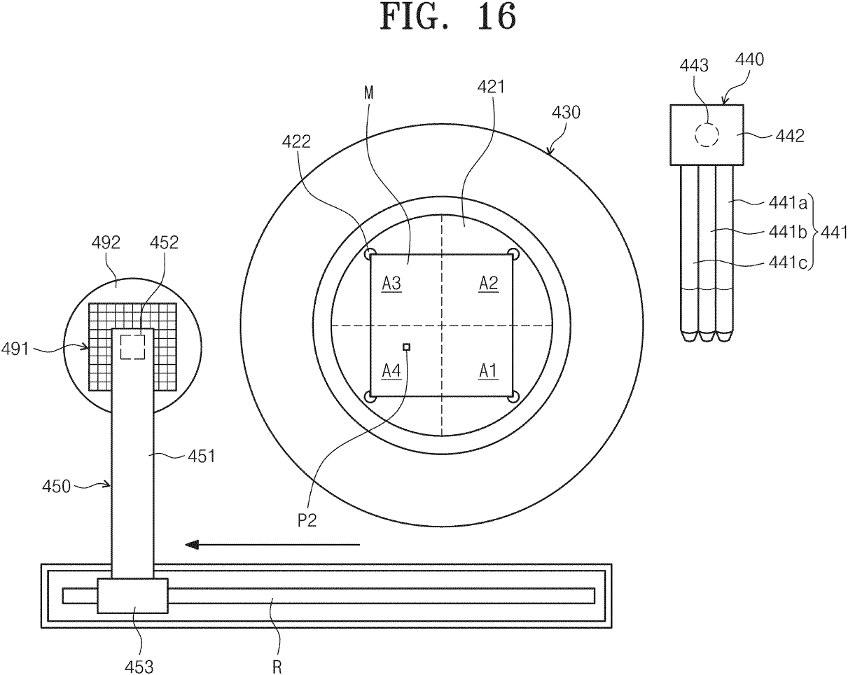

FIG. 15 and FIG. 16 are views illustrating a state of a substrate treating apparatus for performing a heating step of FIG. 10. Referring to FIG. 15 and FIG. 16, in the heating step S42, a substrate M may be heated by irradiating a laser light L to the substrate M. In the heating step S42, the heating unit 450 can heat a substrate M on which a liquid film is formed by irradiating the laser light L to the substrate M. In the heating step S42, a laser irradiation module 460 may heat the substrate M by irradiating the laser light L to the substrate M on which the liquid film is formed by supplying a chemical C.

In the heating step S42, the laser light L may be irradiated to a specific area of the substrate M. In the heating step S42, the laser light L may be irradiated to a heating position. In the heating step S42, the laser irradiation module 460 may move from a standby position to the heating position to irradiate the laser light L to the heating position. In an embodiment, in the heating step S42, the laser irradiator 452 may move to a fourth quadrant A4, which is the heating position, to emit the laser light L toward a second pattern P2 located at the fourth quadrant A4. A temperature of the specific area to which the laser light L is irradiated may be increased. Accordingly, an etching degree by the chemical C of a region to which the laser light L is irradiated may increase. In addition, in the heating step S42, the laser light L may be irradiated to any one of the first pattern P1 or the second pattern P2. For example, the laser light L may be emitted only to the second pattern P2 among the first pattern P1 and the second pattern P2. Accordingly, an etching ability of the chemical C with respect to the second pattern P2 is improved. Accordingly, a critical dimension of the first pattern P1 may be changed from a first width (e.g., 69 nm) to a target critical dimension (e.g., 70 nm). Also, a critical dimension of the second pattern P2 may be changed from a second width (e.g., 68.5 nm) to the target critical dimension (e.g., 70 nm). That is, it is possible to minimize a critical dimension deviation of a pattern formed on the substrate M by improving the etching ability with respect to some regions of the substrate M.

In addition, according to an embodiment of the inventive concept, a moving distance of the laser irradiation module 460 may be minimized by previously moving the second pattern P2 to the heating position irradiating the laser light L. Accordingly, a moving stroke of the laser irradiation module 460 may be minimized, thereby simplifying a structure of the heating unit 450. Accordingly, a structure of the liquid treating chamber 400 may be simplified. In addition, by moving only the minimum distance of the laser irradiator 452, it is possible to minimize a change in a form of a light of the laser irradiation module 460 or a distortion of a position of an irradiating light, which may occur in a process of moving the laser irradiator 452.

In the rinsing step S50, process by-products generated in the etching step S40 may be removed from the substrate M. In the rinsing step S50, a rinsing liquid R may be supplied to a rotating substrate M to remove process by-products formed on the substrate M. In order to dry a rinsing liquid R remaining on the substrate M as necessary, the support unit 420 may rotate the substrate M at a high speed to remove the rinsing liquid R remaining on the substrate M.

In the substrate taking-out step S60, a substrate M which has been treated may be taken out from an inner space 412. In the substrate taking-out step S60, a door may open a taking-in/out port formed at the housing (not shown). In addition, in the substrate taking-out step S60, a transfer robot 320 may unload the substrate M from the support unit 420 and take an unloaded substrate M out of the inner space 412.

In the embodiment of the inventive concept described above, an etching rate of the second pattern P2 is improved at the substrate M having the first pattern P1 which is a monitoring pattern for monitoring a exposing pattern and the second pattern P2 which is a condition setting pattern for treating the substrate. However, unlike this, functions of the first pattern P1 and the second pattern P2 may be different from those of the above-described embodiment of the inventive concept. In addition, according to an embodiment of the inventive concept, only one of the first pattern P1 or the second pattern P2 is provided, and an etching rate of one of the first pattern P1 or the second pattern P2 may be improved. In addition, according to an embodiment of the inventive concept, the same may be applied to improve an etching rate of a specific region on a substrate such as a wafer or a glass other than a photomask.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

1. A mask treating apparatus comprising:
a support unit configured to support and rotate a mask, the mask having a first pattern within a plurality of cells thereof and a second pattern outside regions of the plurality of cells,;
a heating unit including a laser irradiation module and a moving module, the laser irradiation module having a laser irradiator for irradiating a laser light to the second pattern, the moving module configured to change a position of the laser irradiation module; and
a controller configured to control the support unit and the heating unit, and
wherein when a treating position is divided into four equal parts from a first quadrant to a fourth quadrant based on a center of the mask, the laser irradiator is positioned at the fourth quadrant and the first quadrant in a direction linearly moving from a standby position to the treating position, positioned at the third quadrant in a direction which is perpendicular to the fourth quadrant, and positioned at the second quadrant in a direction which is perpendicular to the first quadrant, and
wherein the controller controls a rotation of the support unit so the second pattern is positioned at the fourth quadrant.

2. The mask treating apparatus of claim 1, wherein the controller controls the heating unit so the laser irradiator is moved from the standby position to an irradiation position corresponding to the second pattern positioned at the fourth quadrant, and the laser light is irradiated to the second pattern from the irradiation position.

3. The mask treating apparatus of claim 2, wherein the moving module moves the laser irradiator in a first direction which is horizontal to the ground, and a second direction which is perpendicular to the first direction and horizontal to the ground, and
wherein the fourth quadrant is an area in which a sum of a movement amount in the first direction and a movement mount in the second direction of the laser irradiator is minimized from the standby position to the irradiation position.

4. The mask treating apparatus of claim 3 further comprising a standby port having the laser irradiator positioned at the standby position, and
wherein a monitoring target having an origin matching a center of the laser irradiator when seen from above is provided on the standby port.

5. The mask treating apparatus of claim 4, wherein the heating unit further comprises a camera module in which the laser light irradiated from the laser irradiator acquires an image displayed on the monitoring target and transmits the acquired imaged to the controller.

6. The mask treating apparatus of claim 5, wherein the controller derives a position information of the laser light from the image and calculates a movement amount of the laser irradiator from the standby position to the second pattern positioned at the irradiation position based on the position information.

7. The mask treating apparatus of claim 5, wherein the controller derives a diameter information of the laser light from the image and acquires an information of the laser light irradiated from the laser irradiator based on the diameter information of the laser light.

8. The mask treating apparatus of claim 1, wherein the first quadrant, the second quadrant, the third quadrant, and the fourth quadrant are sequentially positioned in a counter clockwise direction.

9. The mask treating apparatus of claim 1 further comprising:
a liquid supply unit configured to supply a treating liquid to the mask supported on the support unit; and
a container having a treating space for treating the mask and providing a recollecting path for recollecting the treating liquid, and
wherein the support unit supports the mask at the treating space.

10. The mask treating apparatus of claim 1, wherein the controller controls the heating unit so a critical dimension of the first pattern and a critical dimension of the second pattern is minimized by irradiating the laser light with respect to the second pattern.

11. The mask treating apparatus of claim 1, wherein the first pattern provided to each cell is a monitoring pattern of an exposing pattern formed at a cell, and the second pattern is a condition setting pattern of the mask treating apparatus.

12. A substrate treating apparatus comprising:
a support unit configured to support and rotate a substrate having a pattern which is specific formed thereon;
a heating unit configured to heat the pattern; and
a controller configured to control the support unit and the heating unit, and
wherein the controller controls the support unit to move the pattern to a heating position by rotating the substrate, and controls the heating unit so the heating unit moves to a standby position and the heating position.

13. The substrate treating apparatus of claim 12, wherein when a treating position is divided into four equal parts from a first quadrant to a fourth quadrant based on a center of the substrate, the heating unit is positioned at the fourth quadrant and the first quadrant in a direction linearly moving from a standby position to the treating position, positioned at the third quadrant in a direction which is perpendicular to the fourth quadrant, and positioned at the second quadrant in a direction which is perpendicular to the first quadrant, and
the heating position is a position of the pattern when the pattern is positioned at the fourth quadrant.

14. The substrate treating apparatus of claim 13, wherein the heating unit moves in a first direction which is horizontal to the ground, and a second direction which is perpendicular to the first direction and horizontal to the ground, and
wherein the fourth quadrant is an area in which a sum of a movement amount in the first direction and a movement mount in the second direction of the heating unit is minimized from the standby position to an irradiation position.

15-20. (canceled)
